(19) United States
(12) Patent Application Publication
(10) Pub. No.: US 2010/0211335 A1
(43) Pub. Date: Aug. 19, 2010

(54) INFORMATION PROCESSING APPARATUS AND INFORMATION PROCESSING METHOD

(75) Inventor: Junko Gokita, Osaka (JP)

Correspondence Address: HAMRE, SCHUMANN, MUELLER & LARSON P.C., P.O. BOX 2902, MINNEAPOLIS, MN, 55402-0902, US

(73) Assignee: PANASONIC CORPORATION, Kadoma-shi, Osaka (JP)

(21) Appl. No.: 12/679,773

(22) PCT Filed: Sep. 16, 2008
(86) PCT No.: PCT/JP2008/002539

§ 371 Date: Mar. 24, 2010

(30) Foreign Application Priority Data
Sep. 25, 2007 (JP) 2007-247042

(51) Int. Cl. G06F 19/00; G06F 15/00; G01R 21/00

(52) U.S. Cl. 702/56; 702/130; 702/60

(57) ABSTRACT

An information processing apparatus of the present invention includes an HDD status monitoring part 11 that monitors the use environment or use status of a hard disk drive; an HDD status recording part 13 that records the history of the use environment or use status monitored in the HDD status monitoring part 11; a comparing/determining part 14 that compares the history recorded in the HDD status recording part 13 with a predetermined condition; a display part 15 that can output a comparison result in the comparing/determining part 14; and a control part 12 that controls the display part 15 to output the comparison result based on the comparison result in the comparing/determining part 14. When the history satisfies the predetermined condition, the control part 12 controls the display part 15 to output the comparison result. Such a configuration makes it possible to determine, not based on a temporary status change of the use environment but based on the history of the use environment or use status of the HDD, whether the HDD has any abnormality or not, thereby preventing unnecessary notifications from frequently being issued to the user and hence improving the usability.

### TECHNICAL FIELD

The present invention relates to an information processing apparatus and an information processing method capable of determining a use environment of a hard disk drive (HDD) and making a notification of an alert to a user when predetermined reference values are exceeded.

### BACKGROUND ART

Recently, along with the increase in capacity, HDDs have been used in various products such as personal computers and television receivers. However, since the HDD has low resistance to vibration and heat applied from the outside, there is a high possibility of the HDD failing when exposed to strong vibrations or high temperatures. In order to minimize such a HDD failure, a method has been adopted in which a use status or a use environment of the HDD is monitored using a vibration sensor, a temperature sensor or the like, and the user is notified when the HDD status becomes worse. This notification allows the user to take countermeasures, such as backing up data or replacing the HDD.

Patent Documents 1 and 2 disclose a configuration in which the HDD status is monitored using various sensors, and the user is notified when the HDD status becomes worse. Further, Patent Document 3 discloses a configuration in which sounds of mechanical moving parts of a magnetic disk apparatus are collected using microphones, and failures of the magnetic disk apparatus are predicted based on the collected sounds.

FIG. 4 shows a block diagram of a conventional information processing system. In the information processing system shown in FIG. 4, firstly, various sensors 41 detect changes in the operation environment of the HDD. A control part 42 checks results detected by the various sensors 41 and determines whether there is a possibility of inducing HDD errors. The control part 42 controls a display part 43 to display a predetermined notification screen in accordance with a result determined by the control part 42. For example, if the control part 42 determines that there is a possibility of inducing HDD errors, it controls the display part 43 to display a notification screen containing a predetermined message. Thus, the user is alerted, and the HDD failure attributed to the change in the use environment can be suppressed.

[Patent Document 1] JP 2003-345627 A

[Patent Document 2] JP 10(1998)-318804 A

[Patent Document 3] JP 2001-92688 A

### DISCLOSURE OF INVENTION

### Problem to be Solved by the Invention

However, in the conventional configuration described above, the control part 42 determines the presence/absence of abnormality only based on the information at the time when the various sensors 41 detect changes in the operation environment. Because of this, when the temperature of the HDD exceeds a reference value temporarily, or when vibration is applied to the HDD temporarily, the notification screen frequently appears on the display part 43. In other words, even if the temperature is not so high, or the vibration is not so hard as to cause abnormalities in the HDD, the notification screen is displayed frequently on the display part 43, whereby an entry task or the like using the apparatus of the present invention are disturbed.

Therefore, it is an object of the present invention to provide an information processing apparatus and an information processing method that are capable of preventing unnecessary notifications from being issued frequently to the user by determining the presence/absence of abnormality in the HDD, not based on a temporary status change of the use environment but based on the history of the use environment or use status of the HDD, thus improving the usability.

### Means for Solving Problem

An information processing apparatus of the present invention includes: a monitoring part that monitors a use environment or a use status of a hard disk drive; a history recording part that records the history of the use environment or the use status monitored by the monitoring part; a comparing/determining part that compares the history recorded in the history recording part with a predetermined condition; a notification part capable of outputting a comparison result in the comparing/determining part; and a control part that controls the notification part to output the comparison result based on the comparison result in the comparing/determining part, wherein when the history satisfies the predetermined condition, the control part controls the notification part to output the comparison result.

An information processing method of the present invention includes: a monitoring step of monitoring a use environment or a use status of a hard disk drive; a recording step of recording history of the use environment or the use status monitored in the monitoring step; a comparison step of comparing the history with a predetermined condition; and a notification step of outputting a comparison result in the comparison step.

### Effect of the Invention

According to the present invention, it is possible to prevent unnecessary notifications from being issued frequently to the user, whereby the usability can be improved.

### BRIEF DESCRIPTION OF DRAWINGS

FIG. 1 is a block diagram of an information processing apparatus according to an embodiment of the present invention.

FIG. 2 is a flow chart showing an operation flow of a comparing/determining method according to the present embodiment.

FIG. 3 is a perspective view of an information processing apparatus with the screen displaying a comparison result according to the present embodiment.

FIG. 4 is a block diagram of a conventional information processing system.

### DESCRIPTION OF PREFERRED EMBODIMENT

In an information processing apparatus according to the present invention, the monitoring part monitors temperature of the hard disk drive; the comparing/determining part compares the temperature monitored by the monitoring part with a first predetermined value and counts the number of times the temperature exceeds the first predetermined value; and when the number of times exceeds a second predetermined value, the control part controls the notification part to output a comparison result.

In the information processing apparatus according to the present invention, the monitoring part monitors a vibration of the hard disk drive; the comparing/determining part determines whether or not the number of vibrations exceeds a third predetermined value; and when the number of vibrations exceeds the third predetermined value, the control part controls the notification part to output a comparison result.

In the information processing apparatus according to the present invention, the monitoring part monitors power-on time of the hard disk drive; the comparing/determining part compares the power-on time monitored by the monitoring part with a predetermined value and determines whether or not the power-on time exceeds the predetermined value; and when the power-on time exceeds the predetermined value, the control part controls the notification part to output a comparison result.

In the information processing apparatus according to the present invention, the monitoring part executes monitoring at predetermined times.

In the information processing apparatus according to the present invention, the notification part is composed of a display part that is capable of displaying a notification screen containing a content of the comparison result.

The information processing apparatus according to the present invention further includes a reference value obtaining part that obtains a reference value for determining the history of the use environment of the hard disk drive.

The information processing apparatus according to the present invention further includes a first selective part capable of selecting whether or not to output the comparison result in the notification part.

The information processing apparatus according to the present invention further includes a second selective part capable of selecting a content of the comparison result to be output in the notification part.

The information processing apparatus according to the present invention further includes a third selective part capable of selecting whether to output the comparison result automatically in the notification part, or to output the comparison result when a predetermined operation is executed.

The information processing apparatus according to the present invention further includes a power setting obtaining part that obtains power setting information of the apparatus, wherein the control part checks the power setting information obtained by the power setting obtaining part, and controls the notification part to output a notification when the hard disk drive contains power setting information that may cause failures.

In an information processing method according to the present invention, the monitoring step includes monitoring the temperature of the hard disk drive, and the comparison step includes: comparing the temperature monitored in the monitoring step with a first predetermined value; counting the number of times the temperature exceeds the first predetermined value; and when the number of times exceeds a second predetermined value, controlling the notification part to output a comparison result.

In the information processing method according to the present invention, the monitoring step includes monitoring a vibration of the hard disk drive, the comparison step includes: determining whether or not the number of vibrations exceeds a third predetermined value; and when the number of vibrations exceeds the third predetermined value, controlling the notification part to output a comparison result.

In the information processing method according to the present invention, the monitoring step includes monitoring power-on time of the hard disk drive, the comparison step includes: comparing the power-on time monitored in the monitoring step with a fourth predetermined value; determining whether or not the power-on time exceeds the fourth predetermined value; and when the power-on time exceeds the fourth predetermined value, controlling the notification part to output a comparison result.

In the information processing method according to the present invention, the monitoring step executes monitoring at predetermined times.

In the information processing method according to the present invention, in the notification step, a notification screen that contains a content of the comparison result is capable of being displayed on a display part.

The information processing method according to the present invention includes a condition obtaining step of obtaining a condition for making a comparison with the history of the use environment or the use status of the hard disk drive.

In the information processing method according to the present invention, whether or not to output the comparison result in the notification step is selectable.

In the information processing method according to the present invention, a content of the comparison result to be output in the notification step is selectable.

In the information processing method according to the present invention, in the notification step, whether to output the comparison result automatically, or to output the comparison result when a predetermined operation is executed is selectable.

The information processing method according to the present invention further includes an obtaining step of obtaining power setting information of a user; and a control step of checking the power setting information obtained in the obtaining step and controlling the notification part to output a notification when the hard disk drive contains power setting information that may cause failures.

### Embodiment

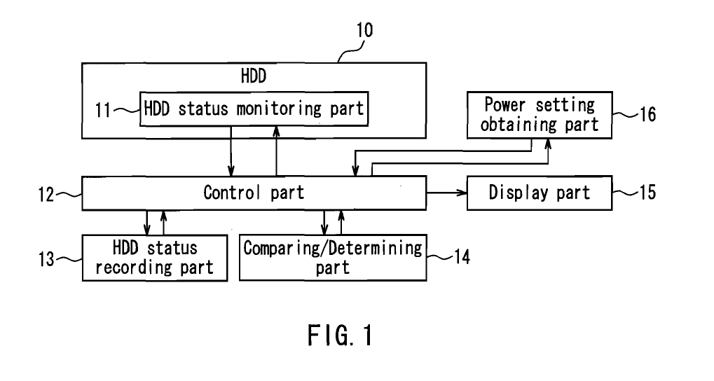

FIG. 1 is a block diagram of an information processing apparatus of the present embodiment. As shown in FIG. 1, the information processing apparatus of the present embodiment includes an HDD 10 with an HDD status monitoring part 11, a control part 12, an HDD status recording part 13, a comparing/determining part 14, a display part 15, and a power setting obtaining part 16.

The HDD status monitoring part 11 is incorporated in the HDD 10. Further, the HDD status monitoring part 11 monitors the use environment of the HDD10 so as to obtain S.M.A.R.T. (Self-Monitoring, Analysis and Reporting Technology) information. The S.M.A.R.T. information contains information such as accumulated power-on time or continuous power-on time of the HDD 10, power-on count of the HDD 10, internal temperature of the HDD 10, and reallocated sector count of the HDD 10. Hereinafter, the S.M.A.R.T. information is referred to as “history information”.

The control part 12 controls the operations of the HDD status monitoring part 11; the HDD status recording part 13; the comparing/determining part 14; the display part 15; and the power setting obtaining part 16.

The HDD status recording part 13 records the history information, which is obtained at the HDD status monitoring part 11, in a predetermined recording area. In the present embodiment, the HDD status recording part 13 records the history information in a registry area. It should be noted that the area where the history information is recorded is not limited to such a registry area, and for example, the history information may be converted into a file format and the converted history information in the file format may be recorded in, for example, memory arranged in the information processing apparatus.

The comparing/determining part 14 reads out the history information recorded at the HDD status recording part 13 and compares the information with predetermined reference values (predetermined conditions). Further, the comparing/determining part 14 determines whether or not the respective values contained in the history information exceed the reference values.

Under the control from the control part 12, the display part 15 can display information such as character information and graphic information. In the present embodiment, on the basis of a determination result at the comparing/determining part 14, the control part 12 controls the display part 15 to display the character information, graphic information or the like, so as to inform that the HDD10 or a personal computer including the HDD 10 is used in inappropriate circumstances. It should be noted that the display part 15 is equivalent to a liquid crystal display mounted on a notebook personal computer, or a display externally connected to a notebook personal computer or a desktop personal computer.

The power setting obtaining part 16 obtains power setting information preset in the information processing apparatus. The power setting information includes setting information for shifting the information processing apparatus to a hibernation state in the case where the idle state of the apparatus continues to a predetermined time. It should be noted that “hibernation state” or “hibernation function” refers to the function of storing the working state information of the information processing apparatus in the HDD and automatically powering off the information processing apparatus. When the apparatus recovers from the hibernation state, the working state information is read out from the HDD and the operation in the working state can be restarted immediately before the apparatus is powered off. The time of the idle state (the time until the shift to a hibernation state) can be set arbitrary by the user.

Hereinafter, the operations of the information processing apparatus will be described.

First, the HDD status monitoring part 11 constantly monitors the operation state (temperature change, vibration, and continuous power-on time in the present embodiment) of the HDD 10 and accumulates the operation state information obtained by monitoring the HDD 10.

At regular intervals or arbitrary timings, the control part 12 demands the present operation state information of the HDD10 from the HDD status monitoring part 11. Based on the demand from the control part 12, the HDD status monitoring part 11 sends history information including the operation state information of the HDD 10 to the control part 12. Then, the control part 12 sends an instruction to the HDD status recording part 13 so that the HDD status recording part 13 records the history information sent from the HDD status monitoring part 11 on a predetermined recording area. Based on the instruction from the control part 12, the HDD status recording part 13 records the history information on the predetermined recording area (registry area in the present embodiment). Next, the control part 12 reads out the history information recorded by the HDD status recording part 13 so as to send the information to the comparing/determining part 14. The comparing/determining part 14 compares values in the history information sent by the control part 12 with predetermined reference values. When the value in the history information exceeds the predetermined reference value, the comparing/determining part 14 sets a flag. It should be noted that a comparing/determining process in the comparing/determining part 14 is executed at a preset timing (for example, 0 minute per hour) or at the time when the user inputs a command for executing the comparing/determining process.

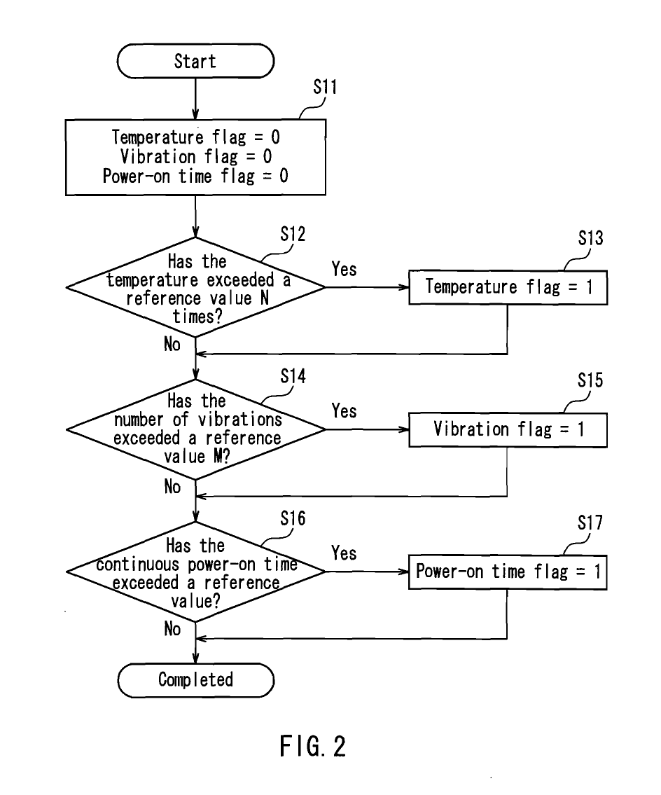

FIG. 2 is a flow chart of a comparing/determining method according to the present embodiment. As shown in FIG. 2, when starting the comparing/determining process, the comparing/determining part 14 sets flags of each of the use environment, i.e. a temperature flag, a vibration flag, and a power-on time flag, at “0” (S11).

Next, the comparing/determining part 14 compares temperature information with a predetermined reference value, referring to the temperature information contained in the history information. Then, the comparing/determining part 14 counts the number of times F1 the temperature information exceeds a reference value T, and thereafter compares the counted number of times F1 with a reference number N (N is an arbitrary value; N=2 in the present embodiment). It should be noted that the reference value T is an example of a first predetermined value of the present invention. Further, the reference number N is an example of a second predetermined value of the present invention (S12).

When the comparing/determining part 14 determines that the number of times F1 exceeds the reference number N, it sets the temperature flag at “1” (S13). When the comparing/determining part 14 determines that the number of times F1 does not exceed the reference number N, the temperature flag is kept at “0” (S13).

Next, the comparing/determining part 14 compares the number of vibrations F2 with a reference number M (M is an arbitrary value; M=1 in the present embodiment), referring to vibration information contained in the history information. It should be noted that the reference number M is an example of a third predetermined value of the present invention (S14).

It should be noted that the number of vibrations may be based on the number of times at which a vibration is sensed by a vibration sensor, or may be based on the number of times only when the degree of vibration exceeds a predetermined level.

When the comparing/determining part 14 determines that the number of vibrations F2 exceeds the reference number M, it sets the vibration flag at “1” (S15). When the comparing/determining part 14 determines that the number of vibrations F2 does not exceed the reference number M, the vibration flag is kept at “0”.

Next, the comparing/determining part 14 determines whether or not continuous power-on time exceeds a reference value E (E=24 hours in the present embodiment), referring to the continuous power-on time information contained in the history information. It should be noted that the reference value E is an example of a fourth predetermined value of the present invention (S16).

When the comparing/determining part 14 determines that the continuous power-on time exceeds the reference value E, it sets the power-on time flag at “1” (S17). When the comparing/determining part 14 determines that the continuous power-on time does not exceed the reference value E, the power-on time flag is kept at “0”.

Thus, the comparing/determining process in the comparing/determining part 14 is completed. In the comparing/determining process shown in FIG. 2, the comparing/determining process is executed in the order of the temperature, vibration, and power-on time, but is not limited to this order.

It should be noted that the counted number may be reset (set to 0) at predetermined times or reset when the information processing apparatus is powered off.

Now, referring to FIG. 1 again, the control part 12 refers to the flags of the use environment set by the comparing/determining part 14, and controls the display part 15 to display a notification screen when at least any one of the temperature flag, the vibration flag, and the power-on time flag is set at “1”. The display part 15, on the basis of the control from the control part 12, displays a notification screen for notifying the user that the HDD 10 is used in inappropriate circumstances.

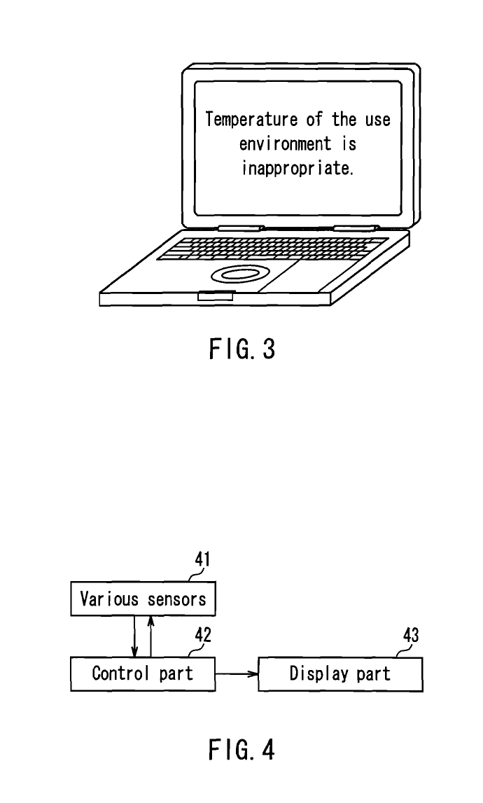

FIG. 3 is an external view of an exemplary information processing apparatus, a notebook personal computer, which shows a state in which a notification screen is displayed on the display part 15. The exemplary display shown in FIG. 3 is a notification screen to be displayed at the time when the temperature flag is at “1”.

It should be noted that a notification screen to be displayed on the display part 15 can be configured so that the screen corresponds to the kind of flags at “1”. For example, when the vibration flag is set at “1”, a message of “I-MD may break because of excessive vibrations in the use environment” can be displayed. Further, when a plurality of flags are set at “1”, a notification screen containing a plurality of messages that correspond to the flags at “1” can be displayed.

In the present embodiment, the notification screen is displayed on the display part 15, but the notification may be made by sound or voice when speakers are incorporated in the information processing apparatus. The notification also may be made by mounting light-emitting diodes to the information processing apparatus for causing the light-emitting diodes to emit light.

In the case of a notebook personal computer, the power setting obtaining part 16 in FIG. 1 obtains information on a set time that is from the start of an idle state until the shift to a hibernation state. Here, when the set time is set short (about one minute, for example), the set time elapses without the user realizing it while he/she is carrying a notebook personal computer in an idle state, or the like, and the process for entering into a hibernation state (a process of writing the working state information immediately before an entrance into the hibernation state to the HDD 10) is executed. If great shocks or vibrations are applied to the notebook personal computer during the execution of the process for entering into the hibernation state, this may cause failures of the HDD 10.

To cope with this, the control part 12 sends the set time information obtained from the power setting obtaining part 16 to the comparing/determining part 14. The comparing/determining part 14 compares the set time information sent from the control part 12 with a preset reference time. As a result of the comparison between the set time and the reference time, if the set time is shorter than the reference time, the comparing/determining part 14 sends the comparison result to the control part 12. Based on the comparison result sent from the comparing/determining part 14, the control part 12 controls the display part 15 to display a notification screen. The display part 15 displays a notification screen based on the control from the control part 12. At this time, the notification image displayed on the display part 15 contains the content indicating that the content of the power setting may become a cause of HDD 10 failures. That is, when the set time is shorter than the reference time, the process for entering into a hibernation state may be executed more frequently; and therefore, the notification for protecting the notebook personal computer from vibrations or shocks is made to the user via the notification screen. However, when the set time is “0”, in other words, when the computer does not shift to a hibernation state even if an idle state continues, the notification is not to be made.

As described above, according to the present embodiment, recording the history information on the use status or use environment of the HDD 10 makes it possible to prevent the notification image from frequently being displayed on the display part 15 due to the temporary status change or environment change of the HDD 10, whereby only necessary notifications are made based on the history information on the use status or use environment.

In the present embodiment, the comparing/determining part 14 compares the temperature information, vibration information and power-on time information that are obtained from the HDD status monitoring part 11 with the reference values, and determines whether there is a cause of inducing HDD 10 errors. However, the element for making comparison and determining factors of inducing HDD 10 errors is not limited to the above-described information. For example, the comparing/determining process similar to the above-described process can be carried out with a configuration in which a reallocation sector process is executed and the number of the reallocated sectors with data written therein is compared with a reference value. The “reallocation sector process” is a process of distributing another sector when a sector in which data is to be written includes an error. This indicates that, if the number of reallocated sectors is large, many sectors in the HDD include errors (bad sectors).

Further, the reference values set at the comparing/determining part 14 may not be fixed values, and may be changeable values or arbitrary values preset by the user. With such a configuration, it is possible to include an input part that allows the user to input reference values as well as a reference value obtaining part that obtains the reference values input by the input part (both of them are not shown).

It also is possible further to include a first selective part that allows the user to select whether or not to display a notification screen on the display part 15.

Further, it is possible to further include a second selective part that allows the user to select a display content of the notification screen to be displayed on the display part 15. For example, only the notification screen for notifying inappropriate temperature of the use environment can selectively be displayed on the display part 15. With this configuration, it is possible to display only a notification screen desired by the user, whereby unnecessary notification screens can be prevented from being displayed.

Still further, it is possible to include a third selective part that allows the user to select whether a notification screen is displayed automatically on the display part 15, or a notification screen is displayed not automatically but arbitrarily only when the user wants to make sure whether the reference values are exceeded.

Still further, in the case of a personal computer, the control part 12, the comparing/determining part 14, and the power setting obtaining part 16 are equivalent to a CPU (Central Processing Unit) and a program that is executed by being read out from the HDD 10 by the CPU. The HDD status recording part 13 is equivalent to a storage area allocated in a disc of the HDD 10. The display part 15 is equivalent to a display that is incorporated in a personal computer or externally connected to a personal computer. The monitoring and notification of the use environment, or the monitoring and notification of the above-described power setting are executed by hardware including the HDD status monitoring part 11 (means for obtaining the S.M.A.R.T. information). Further, the reference value obtaining part and the selective parts described above can be realized by the CPU (Central Processing Unit), the program that is executed by being read out from the HDD by the CPU, and the display, i.e., a display part.

The HDD status monitoring part 11 of the present embodiment is an exemplary monitoring part of the present invention. The HDD status recording part 13 of the present embodiment is an exemplary history recording part of the present invention. Further, the display part 15 of the present embodiment is an exemplary notification part of the present invention. Furthermore, the S.M.A.R.T. information and the history information of the present embodiment are exemplary history and exemplary history information of the present invention.

### INDUSTRIAL APPLICABILITY

By recording the history of the use environment of a hard disk drive (HDD), the information processing apparatus according to the present invention displays screens for alerting the user, not based on a momentary status change of the HDD but based on the case in which the history of the use environment exceeds a predetermined reference value, thereby providing an effect that the user can use the HDD for a longer period. Therefore, the foregoing apparatus is advantageous as a system or the like that alerts the user regarding the use environment of the HDD.

1. An information processing apparatus, comprising:
a monitoring part that monitors a use environment or a use status of a hard disk drive;
a history recording part that records history of the use environment or the use status monitored by the monitoring part;
a comparing/determining part that compares the history recorded in the history recording part with a predetermined condition;
a notification part capable of outputting a comparison result in the comparing/determining part; and
a control part that controls the notification part to output the comparison result based on the comparison result in the comparing/determining part,
wherein the predetermined condition is capable of being changed to an arbitrary condition, and
when the history satisfies the predetermined condition, the control part controls the notification part to output the comparison result.

2. An information processing apparatus, comprising:
a monitoring part that monitors temperature of a hard disk drive;
a comparing/determining part that compares the temperature monitored by the monitoring part with a first predetermined value and counts the number of times the temperature exceeds the first predetermined value;
a notification part capable of outputting a comparison result in the comparing/determining part; and
a control part that controls the notification part to output the comparison result based on the comparison result in the comparing/determining part,
wherein when the number of times exceeds a second predetermined value, the control part controls the notification part to output a comparison result.

3. The information processing apparatus according to claim 1,
wherein the monitoring part monitors a vibration of the hard disk drive,
the comparing/determining part determines whether or not the number of vibrations exceeds a third predetermined value, and
when the number of vibrations exceeds the third predetermined value, the control part controls the notification part to output a comparison result.

4. The information processing apparatus according to claim 1,
wherein the monitoring part monitors power-on time of the hard disk drive,
the comparing/determining part compares the power-on time monitored by the monitoring part with a fourth predetermined value and determines whether or not the power-on time exceeds the fourth predetermined value, and
when the power-on time exceeds the fourth predetermined value, the control part controls the notification part to output a comparison result.

5. The information processing apparatus according to claim 1, wherein the monitoring part executes monitoring at predetermined times.

6. The information processing apparatus according to claim 1, wherein the notification part is composed of a display part capable of displaying a notification screen containing a content of the comparison result.

7. The information processing apparatus according to claim 1, further comprising a reference value obtaining part that obtains a reference value for determining the history of the use environment of the hard disk drive.

8. The information processing apparatus according to claim 1, further comprising a first selective part capable of selecting whether or not to output the comparison result in the notification part.

9. The information processing apparatus according to claim 1, further comprising a second selective part capable of selecting a content of the comparison result to be output in the notification part.

10. The information processing apparatus according to claim 1, further comprising a third selective part capable of selecting whether to output the comparison result automatically in the notification part, or to output the comparison result when a predetermined operation is executed.

11. The information processing apparatus according to claim 1, further comprising a power setting obtaining part that obtains power setting information of the apparatus,
wherein the control part checks the power setting information obtained by the power setting obtaining part, and controls the notification part to output a notification when the hard disk drive contains power setting information that may cause failures.

12. An information processing apparatus, comprising:
a monitoring part that monitors a use environment or a use status of a hard disk drive;
a history recording part that records history of the use environment or the use status monitored by the monitoring part;
a comparing/determining part that compares the history recorded in the history recording part with a predetermined condition;
a notification part capable of outputting a comparison result in the comparing/determining part; and
a control part that controls the notification part to output the comparison result based on the comparison result in the comparing/determining part,
wherein the control part:
outputs the comparison result with respect to the notification part when the history satisfies the predetermined condition, and
controls the history to be reset after a predetermined time elapses, or when the information processing apparatus is powered off.

13. An information processing method, comprising:
a monitoring step of monitoring a use environment or a use status of a hard disk drive;
a recording step of recording history of the use environment or the use status monitored in the monitoring step;
a comparison step of comparing the history with a predetermined condition; and
a notification step of outputting a comparison result in the comparison step,
wherein the predetermined condition is capable of being changed to an arbitrary condition.

14. An information processing method, comprising:
a monitoring step of monitoring temperature of a hard disk drive;
a comparison step of comparing the temperature monitored in the monitoring step with a predetermined condition; and
a notification step of outputting a comparison result in the comparison step,
wherein the comparison step includes:
comparing the temperature monitored in the monitoring step with a first predetermined value,
counting the number of times the temperature exceeds the first predetermined value, and
when the number of times exceeds a second predetermined value, controlling the notification part to output a comparison result.

15. The information processing method according to claim 13,
wherein the monitoring step includes monitoring a vibration of the hard disk drive,
the comparison step includes:
determining whether or not the number of vibrations exceeds a third predetermined value, and
when the number of vibrations exceeds the third predetermined value, controlling the notification part to output a comparison result.

16. The information processing method according to claim 13,
wherein the monitoring step includes monitoring power-on time of the hard disk drive,
the comparison step includes:
comparing the power-on time monitored in the monitoring step with a fourth predetermined value,
determining whether or not the power-on time exceeds the fourth predetermined value, and
when the power-on time exceeds the fourth predetermined value, controlling the notification part to output a comparison result.

17. The information processing method according to claim 13, wherein the monitoring step executes monitoring at predetermined times.

18. The information processing method according to claim 13, wherein, in the notification step, a notification screen containing a content of the comparison result is capable of being displayed on a display part.

19. The information processing method according to claim 13, comprising a condition obtaining step of obtaining a condition for making a comparison with the history of the use environment or the use status of the hard disk drive.

20. The information processing method according to claim 13, wherein whether or not to output the comparison result in the notification step is selectable.

21. The information processing method according to claim 13, wherein a content of the comparison result to be output in the notification step is selectable.

22. The information processing method according to claim 13, wherein, in the notification step, whether to output the comparison result automatically, or to output the comparison result when a predetermined operation is executed is selectable.

23. The information processing method according to claim 13, further comprising:
an obtaining step of obtaining power setting information of a user; and
a control step of checking the power setting information obtained in the obtaining step and controlling the notification part to output a notification when the hard disk drive contains power setting information that may cause failures.

24. An information processing method, comprising:
a monitoring step of monitoring a use environment or a use status of a hard disk drive;
a recording step of recording history of the use environment or the use status monitored in the monitoring step;
a comparison step of comparing the history with a predetermined condition;
a notification step of outputting a comparison result in the comparison step; and
a reset step of resetting the history after a predetermined time elapses, or when the information processing apparatus is powered off,
wherein, in the comparison step, when the history satisfies the predetermined condition, the comparison result is output to the notification part.
